(19) United States
(12) Patent Application Publication
(10) Pub. No.: US 2013/0001746 A1
(43) Pub. Date: Jan. 3, 2013

(54) MULTI-FINGER CAPACITOR WITH REDUCED SERIES RESISTANCE

(75) Inventor: DARVIN RENNE EDWARDS, GARLAND, TX (US)

(73) Assignee: TEXAS INSTRUMENTS INCORPORATED, Dallas, TX (US)

(21) Appl. No.: 13/175,554

(22) Filed: Jul. 1, 2011

(51) Int. Cl. H01L 29/92; H01L 21/02

(52) U.S. Cl. 257/534; 438/381; 257/E29.342; 257/E21.008

(57) ABSTRACT

An electronic die includes a multi-finger capacitor including a first electrically conductive plate including a plurality of first metal fingers joined together by a first metal base, and a second electrically conductive plate including a plurality of second metal fingers joined together by a second metal base. A dielectric layer is between the first electrically conductive plate and the second electrically conductive plate for electrically isolation. The plurality of first metal fingers and plurality of second metal fingers are interleaved with one another. The die can include a first portion that includes the multi-finger capacitor and a second portion that includes active circuitry configured to provide at least one circuit function, wherein the first and second electrically conductive plates are coupled to the active circuitry.

### FIELD

Disclosed embodiments relate to capacitor structures that include multiple fingers.

### BACKGROUND

As known in the art, through-substrate vias (referred to herein as TSVs), which are commonly referred to as through-silicon vias in the case of silicon substrates, are vertical electrical connections that extend from one of the electrically conductive levels formed on the topside of a substrate wafer or semiconductor die (e.g., the contact level or one of the metal interconnect levels such as metal 1) to its bottomside. The vertical electrical paths are significantly shortened relative to conventional wire bonding technology, generally leading to significantly faster device operation.

Regarding fabrication of TSVs, in a typical via-first process, for example, vias are formed to a depth (e.g., 100 to 200 μm) that is significantly less than the full wafer thickness (e.g., 300 to 800 μm) using chemical etching, laser drilling, or one of several energetic methods, such as Reactive Ion Etching (RIE). Once the vias are formed, they are generally framed with a dielectric liner (or sleeve) from about 0.2 μm to 5 μm thick to provide electrical isolation from the surrounding semiconductor substrate, and are then made electrically conductive by filling the vias with an electrically conductive filler material (e.g., copper, tungsten, or doped polysilicon) to form embedded TSVs.

The bottom of the embedded TSV is generally referred to as an embedded TSV tip. Since most electrically conductive filler materials are metals that can degrade minority carrier lifetimes (e.g., copper or tungsten) in the semiconductor, a metal diffusion barrier layer is generally deposited on the dielectric liner. The metal diffusion barrier layer is typically 100-500 Å thick. In the case of an electroplated metal (e.g., copper) process, a seed layer is generally added after the metal diffusion barrier layer before electroplating the metal. A backgrinding step is then conventionally used to thin the substrate wafer by removing a sufficient thickness of the substrate (e.g., 50 to 300 μm) from its bottomside to reach the embedded TSV tip to expose the electrically conductive filler material at the distal end of the TSV tip.

TSV-based capacitors are known for integrated passive applications, such as for storage capacitors in DC/DC power converters. In such capacitors, the substrate, such as silicon, forms one plate of the capacitor. These capacitors have advantages in that their dielectric sleeve thicknesses can be very thin (e.g., 0.2 μm to 1 μm) and their areas can be large to allow high capacity in very small volumes (high capacitance density). However, a disadvantage of TSV-based capacitors is the significant series resistance of the substrate (e.g., silicon) plate of the capacitor. For example, this series resistance creates an efficiency loss for power converters which use such TSV-based capacitors.

### SUMMARY

Disclosed embodiments describe electronic die having at least one multi-finger capacitor that reduces the series resistance of the substrate (e.g., silicon) plate compared to conventional TSV-based capacitors by replacing this substrate plate with a metal plate. In one embodiment the substrate material (e.g., silicon) of the die is completely etched away in the portion of the die that includes the capacitor (referred to herein as “the first portion”) to expose the dielectric sleeve coated first metal fingers, followed by formation of a replacement metal plate including second metal fingers to form a multi-finger through-die capacitor, hereafter referred to as a “through-die” capacitor which as used herein means the multi-finger capacitor extends the full distance from one side of the die to the other side of the die.

One embodiment comprises deposition of a seed layer then plating Cu, and plating up a full layer of the metal to become the second capacitor plate. Metals such as aluminum, copper, copper alloys, nickel and silver, which have significantly less resistance as compared to the removed semiconductor material, can be used for the replacement metal plate, thus improving the efficiency of the capacitor.

In one embodiment the electronic die comprises a first portion that includes the multi-finger capacitor and a second portion that includes active circuitry configured to provide at least one circuit function. In this embodiment the first and second electrically conductive plates of the multi-finger capacitor are coupled to active circuitry on the die.

### BRIEF DESCRIPTION OF THE DRAWINGS

FIG. 1 is a flow diagram illustrating an example method for forming an electronic die including at least one through-die capacitor, according to an example embodiment.

FIGS. 2A-D are cross-sectional views of intermediate structures corresponding to various steps in the example method shown in FIG. 1, according to an example embodiment.

FIG. 3 shows an example through-die capacitor die, according to an example embodiment.

FIG. 4 is a flow diagram illustrating an example method for forming electronic die including at least one through-die capacitor on a first portion of the die and active circuitry on a second portion of the die, according to an example embodiment.

FIG. 5A shows an example electronic die including at least one through-die capacitor on a first portion of the die and active circuitry on a second portion of the die, according to an example embodiment.

FIG. 5B shows an example electronic die including at least one through-die capacitor on a first portion of the die and active circuitry on a second portion of the die, according to another example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

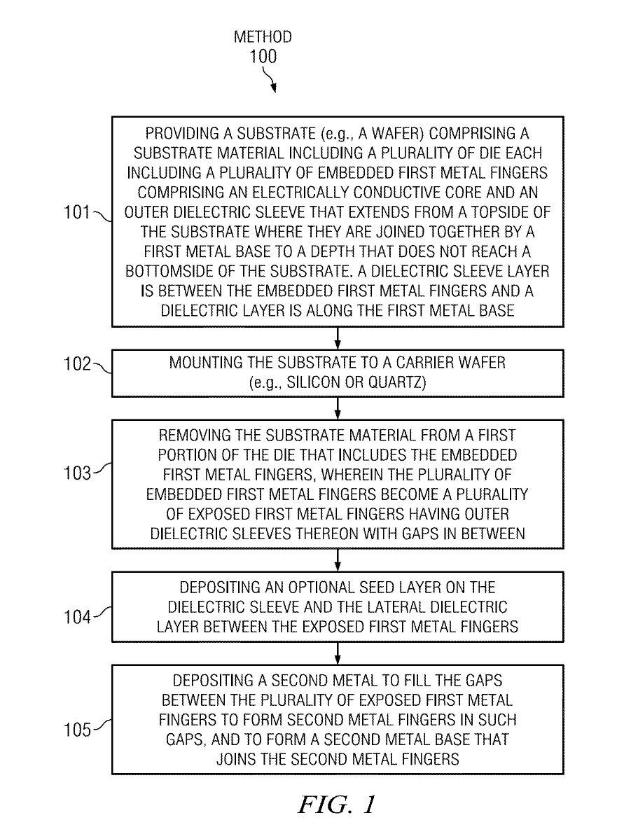

FIG. 1 is a flow diagram illustrating an example method 100 for forming electronic die including at least one through-die capacitor, according to an example embodiment. Step 101 comprises providing a substrate (e.g., a wafer) referred to herein as a “wafer” comprising a substrate material including a plurality of die each including a plurality of embedded first metal fingers comprising an electrically conductive core and an outer dielectric sleeve that extends from a topside of the substrate where they are joined together by a first metal base to a depth that does not reach a bottomside of the substrate. The substrate material generally comprises a semiconductor, such as silicon or silicon/germanium, but can comprise other substrate materials.

A dielectric sleeve layer is between the embedded first metal fingers, and a dielectric layer is along the first metal base (referred to herein as the “lateral dielectric layer”). The embedded first metal fingers can be formed by first etching deep pits (vias) in a semiconductor wafer (e.g., a Si wafer) using an etch process such as reactive ion etching (RIE). This is a standard process which is used to form TSVs. The dielectric sleeve layer and lateral dielectric layer are then formed.

The dielectric sleeve and lateral dielectric layer can comprise materials such as silicon oxide, silicon nitride, phosphorus-doped silicate glass (PSG), silicon oxynitride, or certain CVD polymers (e.g., parylene). The dielectric sleeve and lateral dielectric layer can be as thin as 25 Å (for low voltage applications, e.g., <2.5 V), such as being 0.05 to 5 μm thick, and can be 0.1 to 1 μm thick in one embodiment.

In one particular embodiment the dielectric sleeve and lateral dielectric layer comprise a thermally grown silicon oxide layer that frames the embedded vias and also grows on the substrate surface lateral to the vias. Alternatively, a higher dielectric constant (high-k) material (e.g., a metal oxide or metal nitride) can be formed using processes such as atomic layer deposition (ALD). As used herein a high-k dielectric material has a k-value of at least 10 (about 2.5× the k-value for silicon dioxide). A high-k dielectric as compared to conventional silicon oxide will provide a higher capacitance. Deposition of the dielectric is generally isotropic in nature to deposit dielectric in the embedded vias as well as lateral to the embedded vias to form the lateral dielectric layer on the substrate surface.

In the case of copper and certain other metals for the first metal which provides the electrically conductive core for the embedded first metal fingers, a metal diffusion barrier layer is generally added before first metal deposition, such as a refractory metal or a refractory metal nitride. For example, metal barrier materials can include materials including Ta, W, Mo, Ti, TiW, TiN, TaN, WN, TiSiN or TaSiN, which can be deposited by physical vapor deposition (PVD) or chemical vapor deposition (CVD). The metal diffusion barrier layer is typically 100-500 Å thick.

Step 102 comprises mounting the wafer to a carrier wafer (e.g., silicon or quartz), for example, in the same general fashion as would be performed for backgrinding or backside etching to expose the embedded first metal fingers in a conventional TSV process that forms TSV tips, such as using a suitable adhesive. The carrier wafer enables handling of the wafer after the substrate material (e.g., Si) has been etched off in step 103 described below. This is a process which is common for conventional TSV processing.

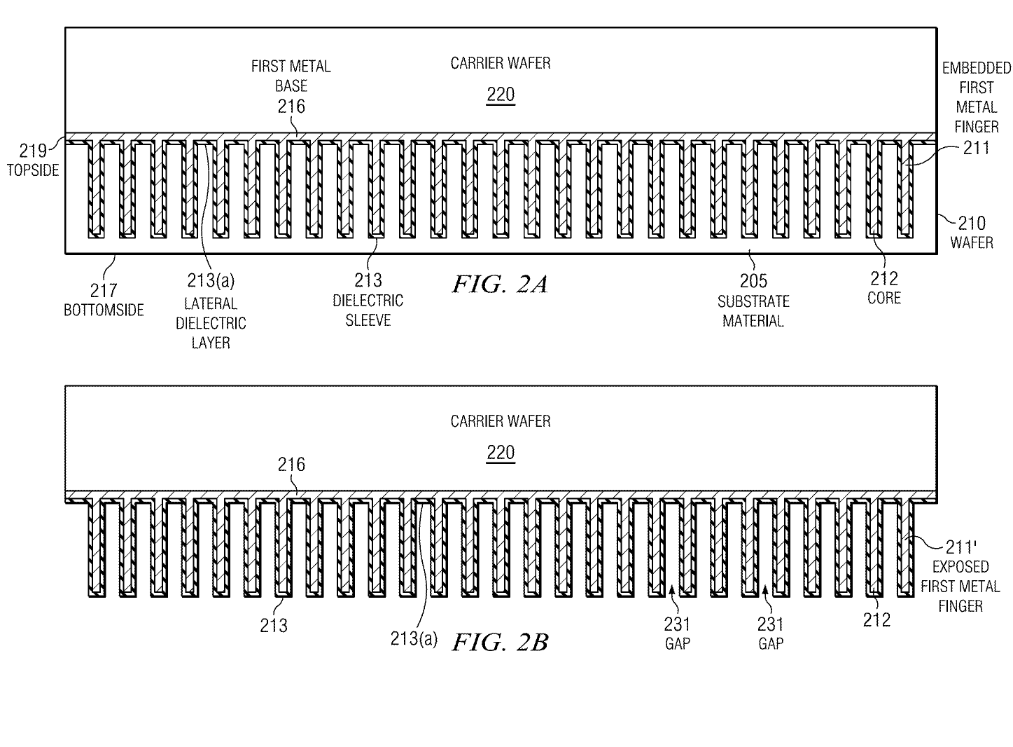

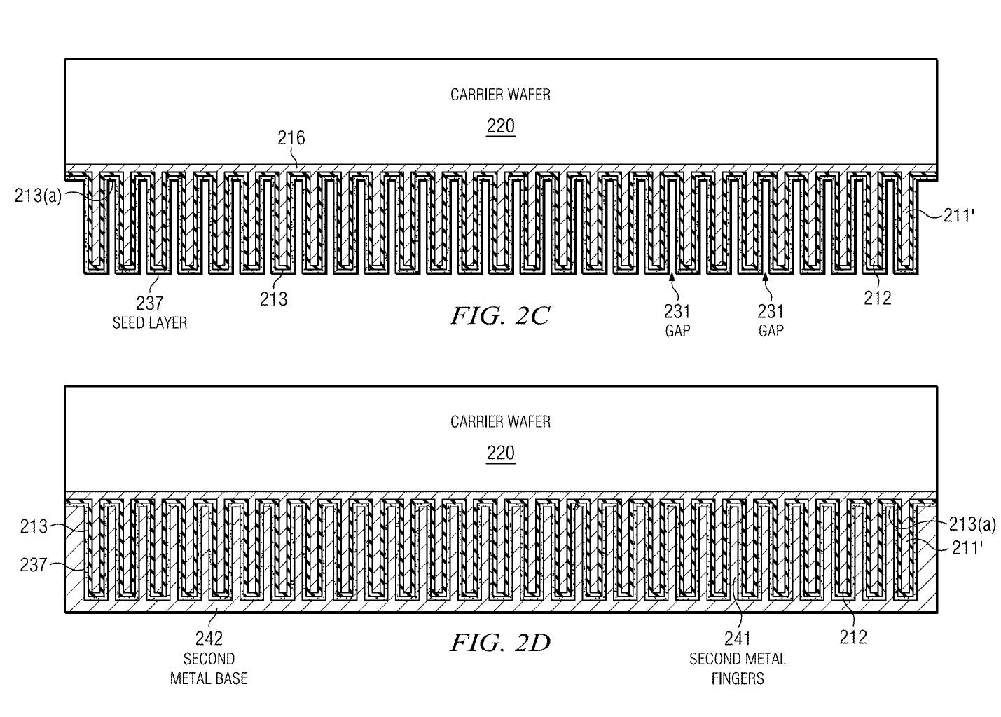

FIG. 2A shows a cross sectional depiction of a wafer 210 after being bonded to a carrier wafer 220. An adhesive that is ordinarily between the wafer and carrier wafer is not shown for simplicity. The wafer 210 includes a substrate 205 (e.g., silicon substrate), a plurality of embedded first metal fingers 211 comprising an electrically conductive core 212, and an outer dielectric sleeve 213 that extends from a topside 219 of the wafer 210 where they are joined together by a first metal base 216. The embedded first metal fingers 211 do not extend to a depth that reaches a bottomside 217 of the wafer 210. A lateral dielectric layer 213(a) which can be the same material and can be formed simultaneously with the dielectric sleeve 213 is between the embedded first metal fingers 211 along the bottom surface of the first metal base 216. There is no limit to the shape of the metal fingers disclosed herein, so that the metal fingers can be in a variety of shapes including cylindrical, rectangular, as well as other shapes such as elliptical.

Step 103 comprises completely removing the substrate material 205, wherein the plurality of embedded first metal fingers 211 become a plurality of exposed first metal fingers 211′ as shown in FIG. 2B having outer dielectric sleeves 213 thereon. The entire structure can be seen to be exclusive of any substrate material. A mechanical backgrind nearly to the bottom of the embedded first metal fingers 211 can substantially reduce the time required for an etch to remove the substrate material, such as using an etch solution. The etch solution can be any of a number of common orientation dependent etch chemistries. Such etches attack the substrate material such as silicon, but are highly to selective to not etch the silicon oxide or other dielectrics in dielectric sleeve 213 and lateral dielectric layer 213(a). Hydroxides such as KOH (potassium hydroxide) and TMAH (Tetramethylammonium hydroxide) may be used for silicon etching, for example.

Following step 103 the lateral dielectric layer 213(a) also remains on the first metal base 216 between the plurality of exposed first metal fingers 211′. Gaps 231 can be seen in FIG. 2B to be formed between adjacent ones of the plurality of exposed first metal fingers 211′.

Step 104 comprises depositing an optional plating seed layer 237 before plating metals such as copper on the dielectric sleeve 213 and on the lateral dielectric layer 213(a) between the exposed first metal fingers 211′ as shown in FIG. 2C. The seed layer 237 can be deposited by plasma deposition or electrolessly plating, and in one embodiment comprises Pd. In one embodiment an electroless plating solution is used to form the seed layer 237 on the exposed dielectric layers 213, 213(a). For example, electroless Pd is commonly used as seed layers in printed circuit board (PCB) processes.

Step 105 comprises depositing, such as by plating, a second metal to fill the gaps 231 between the plurality of exposed first metal fingers 211′ to form second metal fingers 241 in the gaps 231, and to form a second metal base 242 that joins the second metal fingers 241 as shown in FIG. 2D. The second metal can comprise copper in one embodiment to provide a low resistance metal plate. As described above, other example second metals include aluminum, copper alloys, nickel and silver. The thickness of the second metal base 242 can generally be 0.1 μm to 10 s of μms.

Surface smoothing can be obtained through polishing (e.g., chemical mechanical polishing (CMP)) if desired. Following step 105, each die on the wafer has a disclosed through-die capacitor, where exposed first metal fingers 211′ and the second metal fingers 241 are interleaved (i.e., interdigitated in 3 dimensions) with one another.

Step 106 comprises optionally adding a metal capping layer to one or both plates of the through-die capacitors, such as a metal or metal alloy that enhances solderability. One example metal capping layer comprises NiAu plating.

The wafer can be singulated by sawing to whatever size is desired to produce a plurality of singulated through-die capacitor die. A weak metal etch solution can be used after singulating to remove about 1 μm of metal to ensure the sawn edges do not short across the dielectric.

Disclosed embodiments include a variety of related process flows. One process flows deposits the capacitor dielectric after the substrate material is removed. For example, a chemical vapor deposition (CVD) oxide can be applied after the substrate material is removed. In another process flow, a liquid (solvent) with a dielectric can be deposited. If the concentration of the dielectric in the solvent is low, a thin dielectric film can be formed.

It is also possible to form disclosed multi-finger capacitors that are on a substrate material such as a silicon substrate (thus are not “through-die”) by forming a metal layer on the substrate, forming deep pits in the metal layer, framing the pits with a dielectric, and then depositing another metal layer thereon. Moreover, it is also possible to realize a through-die capacitor structure by starting with a block of metal (e.g., copper) as the substrate to avoid the need for a conventional substrate. In this process selective pits can be formed in the metal block using a photo resist and removal process to form the first metal fingers, which can then be framed with dielectric followed by second metal deposition to form the second metal fingers and a second metal base coupled to the second metal fingers.

For example, a method of fabricating capacitors can comprise removing a patterned portion of a substrate from a top surface to form at least a first depression (e.g., via or pit), filling the depression with a first metal to form a first electrode of a capacitor. A portion of the substrate is removed which surrounds the first depression from a bottom surface opposite the top surface to form at least a second depression and expose a surface of the first electrode. A dielectric film is formed over a surface of the first electrode. The second depression is filled with a second metal to form a second electrode of the capacitor, where the dielectric film is positioned between the first electrode and second electrode. The substrate can comprise a metal substrate, or a non-metallic substrate.

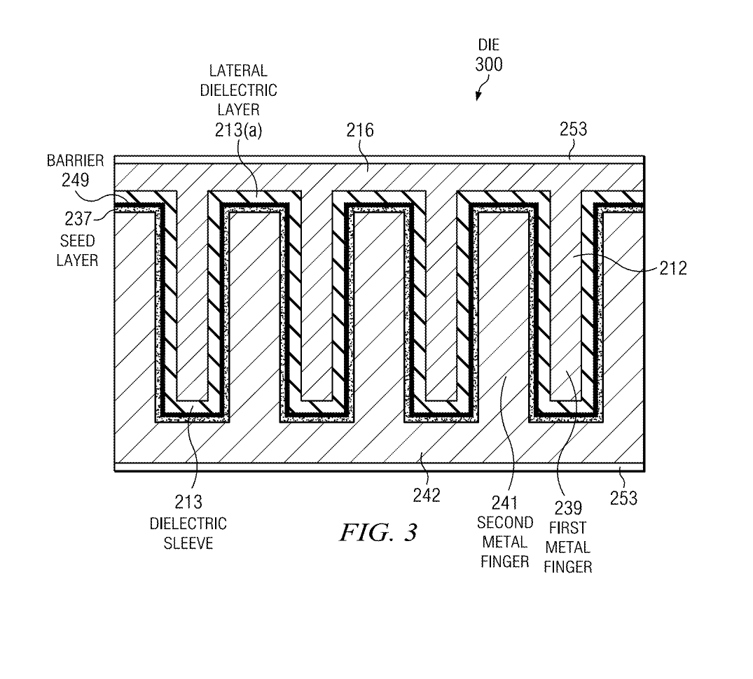

FIG. 3 shows an example multi-finger through-die capacitor die 300, according to an example embodiment. Die 300 represents the structure following adding the capping metal layer 253 to both plates/terminals of the through-die capacitor (step 106), followed by singulation. The first metal fingers 239 (which correspond to the exposed first metal fingers 211′ described above) can be seen to be interleaved with the second metal fingers 241. The interleaving is a 3-dimensional interleaving as the interleaving is over the full thickness of die 300. An optional diffusion barrier layer 249 is on the dielectric sleeve 213 and on the lateral dielectric layer 213(a), with a seed layer 237 on the diffusion barrier layer 249. The die 300 can be seen to be exclusive of any substrate material (e.g., silicon). Moreover, outer ones of the plurality of second metal fingers 241 can be seen to provide outer sidewalls for the die 300.

Disclosed multi-finger through-die capacitors such as die 300 shown in FIG. 3, lower the series resistance of the bottomside plate of conventional TSV-based capacitors by replacing the high series resistance semiconductor bottomside plate material such as silicon with a low series resistance metal, such as aluminum, copper, copper alloys, nickel or silver. The series resistance of the bottomside plate can be lowered further by using a relatively thick second metal base 242, such as 2 μm to 50 μm thick.

Disclosed through-die capacitors provide several significant advantages over conventional TSV-based capacitors. For example, in power applications, the lower series resistance reduces parasitic power dissipation which is dissipated by current flowing through the semiconductor (e.g., Si) substrate associated with conventional bottomside plates. Lower series resistance allows the switching speed of devices such as power regulators to be higher, reducing the need for higher capacitance values. For RF applications (e.g., switching devices that switch up to 100 GHz), lower series resistance provided by disclosed through-die capacitors increases the effective capacitance of the structure which is otherwise limited by the series resistance.

Although described above for electronic die that include only through-die capacitors, disclosed embodiments may be used for integrated passive devices, and also for integrated circuits. The integrated circuit embodiment comprises at least one disclosed through-die capacitor on a first portion of the die and active circuitry on a second portion of the die. This IC embodiment enables high capacitance values with low series resistances for on-chip applications.

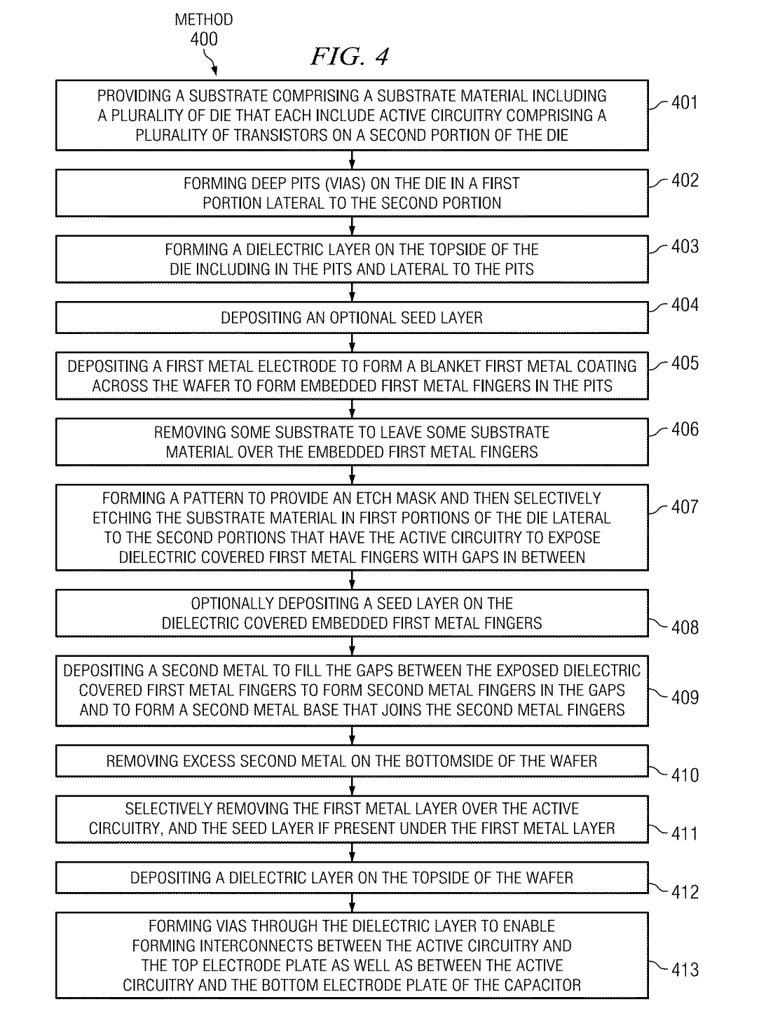

FIG. 4 is a flow diagram illustrating an example method 400 for forming electronic die including at least one multi-finger through-die capacitor on a first portion of the die and active circuitry on a second portion of the die, according to an example embodiment. Step 401 comprises providing a substrate (e.g., a wafer) comprising a substrate material including a plurality of die that each include active circuitry comprising a plurality of transistors on the second portion, such as after front end of the line (FEOL) processing is complete. The substrate material generally comprises a semiconductor, such as silicon or silicon/germanium, but can comprise other substrate materials. Step 402 comprises forming deep pits (vias) on the die in a first portion lateral to the second portion, such as using standard etch technologies (e.g., plasma removal).

Step 403 comprises forming a dielectric layer on the topside of the die including in the etched pits and lateral to the etched pits. The dielectric layer can comprise materials such as silicon oxide, silicon nitride, phosphorus-doped silicate glass (PSG), silicon oxynitride, or certain CVD polymers (e.g., parylene). In one particular embodiment the dielectric layer comprises a thermally grown silicon oxide layer. Alternatively, a higher dielectric constant (high-k) material (e.g., a metal oxide or metal nitride) can be formed using processes such as ALD.

Step 404 comprises depositing an optional seed layer analogous to step 104 described above relative to FIG. 1. Step 405 comprises depositing a first metal electrode, for example, by plating copper, to form a blanket first metal coating across the wafer to form embedded first metal fingers in the pits. Step 406 comprises removing some of the substrate material, such as by backgrinding the wafer, to a preset limit the leave some substrate material over the embedded first metal fingers.

Step 407 comprises forming a pattern to provide an etch mask and then selectively etching the substrate material in the first portions, where the etch mask protects the substrate material in the second portions. This step can include using infrared (IR) imaging through the substrate to “see” the embedded first metal fingers. Etching of the substrate in step 407 exposes the dielectric covered first metal fingers, and is a selective etch variant of step 103 described above relative to FIG. 1.

Step 408 comprises optionally depositing a seed layer on the dielectric covered embedded first metal fingers analogous to step 104 described above relative to FIG. 1. Step 409 comprises depositing, such as by plating, a second metal to fill the gaps between the plurality of exposed dielectric covered first metal fingers to form second metal fingers in the gaps between the first metal fingers, and to form a second metal base that joins the second metal fingers, generally to a thickness to extend beyond the depth of the substrate material on the bottomside of the wafer. Step 409 is analogous to step 105 described above relative to FIG. 1. The second metal can comprise copper in one embodiment to provide a low resistance metal plate. As described above, other example second metals include aluminum, copper alloys, nickel and silver. The thickness of the second metal base can generally be 0.1 μm to 10 s of μms.

Step 410 comprises removing excess second metal on the bottomside of the wafer, such as by CMP. Step 411 comprises selectively removing the first metal layer over the active circuitry, and the seed layer if present under the first metal layer. Step 412 comprise depositing a dielectric layer on the topside of the wafer. Step 413 comprises forming vias through this dielectric layer to enable forming interconnects between the active circuitry and the first metal of the through-die capacitor which functions as the top electrode plate for the capacitor as well as between the active circuitry and the second metal of the capacitor which functions as the bottom electrode plate of the capacitor.

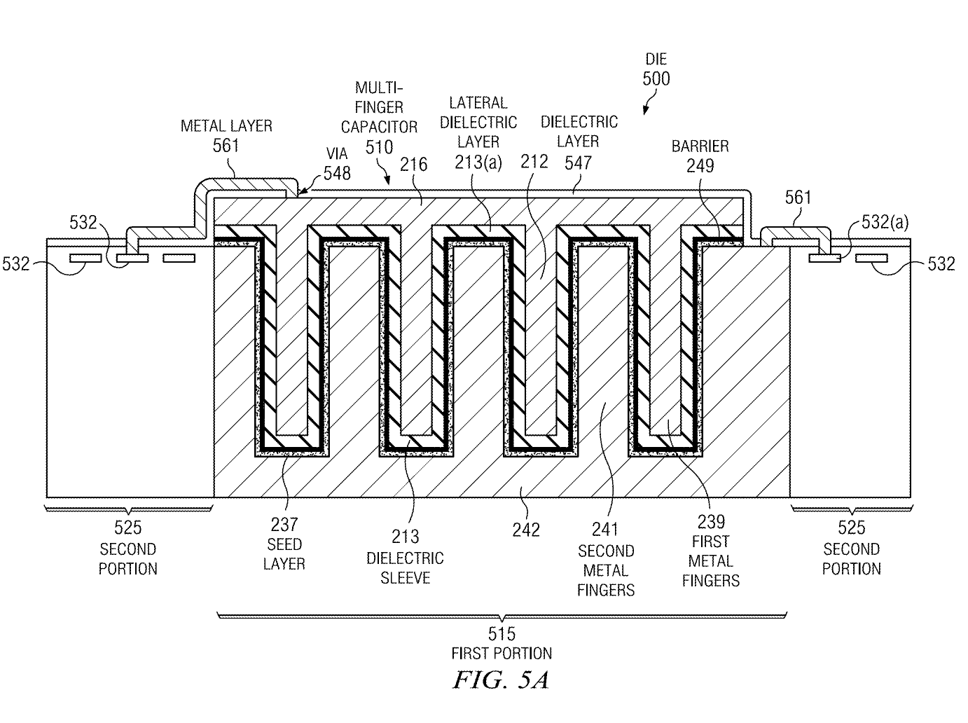

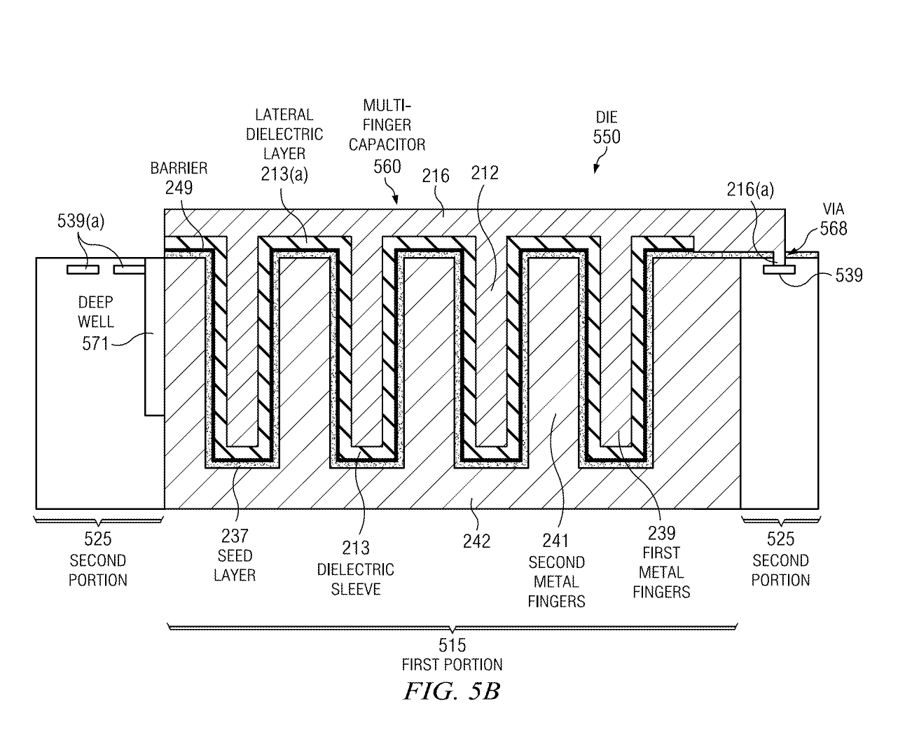

In an alternate embodiment (see FIG. 5B described below for a depiction of the resulting structure), steps 412 and 413 can be replaced by the following alternate contact flow. During the FEOL process flow highly doped deep well diffusions can be formed in the second portion of the die that includes the active circuitry. The bottom electrode plate of the capacitor can be connected to the active circuitry using the highly doped/deep well diffusion (to provide low resistance). In this embodiment the top electrode of the capacitor can be connected to the active circuitry on the die using vias which existed prior to formation of the first metal. In one particular embodiment the active circuitry implements a power controller function.

FIG. 5A shows an example electronic die 500 including at least one through multi-finger through-die capacitor 510 on a first portion 515 of the die 500 and active circuitry on a second portion 525 of the die, according to an example embodiment. A dielectric layer 547 is on the topside of the die 500, and has vias 548 formed therein. Respective vias 548 to allow metal layer 561 to couple active circuitry 532 on second portion 525 to the top plate of the capacitor 510 though connection to first metal base 216, and metal layer 561 to couple other active circuitry shown as 532(a) on the second portion 525 to the bottom plate of the capacitor 510 though connection to the second metal base 242.

FIG. 5B shows an example electronic die 550 including at least one through multi-finger through-die capacitor 560 on a first portion of the die 515 and active circuitry 539, 539(a) on a second portion 525 of the die, according to another example embodiment. Bottom plate contacts are provided by active circuitry 539(a) coupled to deep well 571, where the deep well 571 is connected to the second metal base 242, with top plate coupling for through-die capacitor to active circuitry 539 provided by first metal base portion 216(a) though via 568 to active circuitry 539.

The active circuitry formed on the wafer or substrate comprises circuit elements that may generally include transistors, diodes, capacitors, and resistors, as well as signal lines and other electrical conductors that interconnect the various circuit elements. Disclosed embodiments can be integrated into a variety of process flows to form a variety of devices and related products. The semiconductor substrates may include various elements therein and/or layers thereon. These can include barrier layers, other dielectric layers, device structures, active elements and passive elements, including source regions, drain regions, bit lines, bases, emitters, collectors, conductive lines, conductive vias, etc. Moreover, disclosed embodiments can be used in a variety of semiconductor device fabrication processes including bipolar, CMOS, BiCMOS and MEMS processes.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. An electronic die, comprising:
a multi-finger capacitor, said capacitor including:
a first electrically conductive plate including a plurality of first metal fingers joined together by a first metal base;
a second electrically conductive plate including a plurality of second metal fingers joined together by a second metal base, and
a dielectric layer between said first electrically conductive plate and said second electrically conductive plate for electrically isolating said first electrically conductive plate and said second electrically conductive plate from one another,
wherein said plurality of first metal fingers and said plurality of second metal fingers are interleaved with one another.

2. The electronic die of claim 1, wherein outer ones of said plurality of second metal fingers provide outer sidewalls for said capacitor.

3. The electronic die of claim 1, wherein said capacitor is exclusive of any semiconductor material and said capacitor is a through-die capacitor.

4. The electronic die of claim 1, wherein said dielectric layer comprise a high-k dielectric layer having a k-value of at least 10.

5. The electronic die of claim 1, further comprising at least one metal capping layer for enhancing solderability on said first metal base or said second metal base.

6. The electronic die of claim 1, further comprising a metal diffusion barrier layer on said dielectric layer and between said first electrically conductive plate and said second electrically conductive plate.

7. The electronic die of claim 1, wherein said first metal fingers, said first metal base, said second metal fingers and said second metal base all comprise copper.

8. The electronic die of claim 1, wherein said die comprises a first portion that includes said capacitor and a second portion that includes active circuitry configured to provide at least one circuit function, wherein said first and said second electrically conductive plates are coupled to said active circuitry.

9. The electronic die of claim 8, wherein said circuit function comprises a power controller function.

10. A method of forming electronic die including multi-finger capacitors, comprising:
providing a substrate including a substrate material having a plurality of die each including a plurality of embedded first metal fingers having an electrically conductive core and an outer dielectric sleeve that extends from a topside of said substrate where they are joined together by a first metal base to a depth that does not reach a bottomside of said substrate, and wherein a lateral dielectric layer is between said embedded first metal fingers along said first metal base;
removing said substrate material from a first portion of said die that includes said embedded first metal fingers, wherein said plurality of embedded metal fingers become a plurality of exposed first metal fingers having said outer dielectric sleeves thereon, wherein said dielectric layer remains on said first metal base between said plurality of exposed first metal fingers, and wherein gaps are formed between adjacent ones of said plurality of exposed first metal fingers, and
depositing a second metal to fill said gaps between said plurality of exposed first metal fingers to form second metal fingers in said gaps and to form a second metal base that joins said second metal fingers,
wherein a plurality of said capacitors are formed having a first electrically conductive plate comprising said plurality of first metal fingers and a second electrically conductive plate comprising said plurality of second metal fingers, and wherein said first metal fingers and said second metal fingers are interleaved with one another.

11. The method of claim 10, wherein said substrate material comprises silicon, and said removing comprises a wet etch.

12. The method of claim 10, wherein outer ones of said plurality of second metal fingers provide outer sidewalls for said plurality of capacitors.

13. The method of claim 10, wherein said plurality of capacitors are exclusive of any of said substrate material and said capacitor is a through-die capacitor.

14. The method of claim 10, wherein said dielectric layer comprise a high-k dielectric layer having a k-value of at least 10.

15. The method of claim 10, wherein said outer dielectric sleeve and said lateral dielectric layer comprise a high-k dielectric layer having a k-value of at least 10.

16. The method of claim 10, further comprising forming a metal capping layer for enhancing solderability on at least one of said first metal base or said second metal base.

17. The method of clam 10, wherein said first metal fingers, said first metal base, said second metal fingers, and said second metal base all comprise copper.

18. The method of claim 10, further comprising mounting said substrate to a carrier before said removing, wherein said first portion is all of said die, and wherein said removing removes all said substrate material from said die.

19. The method of claim 10, wherein said die further comprises a second portion lateral to said first portion that includes active circuitry configured to provide at least one circuit function that is masked during said removing step.

20. The method of claim 19, wherein said first electrically conductive plate and said second electrically conductive plate are both coupled to said active circuitry.

21. A method of fabricating capacitors, comprising:
removing a patterned portion of a substrate from a top surface to form at least a first depression;
filling said depression with a first metal to form a first electrode of a capacitor;
removing a portion of said substrate which surrounds said first depression from a bottom surface opposite said top surface to form at least a second depression and expose a surface of said first electrode;
forming a dielectric film over said surface of said first electrode, and
filling said second depression with a second metal to form a second electrode of said capacitor;
wherein said dielectric film is between said first electrode and said second electrode.

22. The method of claim 21, wherein said substrate comprises a non-metallic substrate.
